(19) United States
(12) Patent Application Publication
(10) Pub. No.: US 2003/0068573 A1
(43) Pub. Date: Apr. 10, 2003

(54) Chemical amplification type positive resist composition

(76) Inventors: Yoshiyuki Takata, Osaka (JP); Hiroaki Fujishima, Osaka (JP); Yasunori Uetani, Osaka (JP)

Correspondence Address: BIRCH STEWART KOLASCH & BIRCH, PO BOX 747, FALLS CHURCH, VA, 22040-0747, US

(21) Appl. No.: 10/207,997

(22) Filed: Jul. 31, 2002

(30) Foreign Application Priority Data
Aug. 2, 2001 (JP) 2001-234649

(51) Int. Cl. G03F 7/004

(52) U.S. Cl. 430/270.1; 430/914; 430/921; 430/910

(57) ABSTRACT

A chemical amplification type positive resist composition is provided which gives resist patterns showing remarkably improved line edge roughness and comprises an acid generator containing a benzenesulfonate ion of the formula (I):

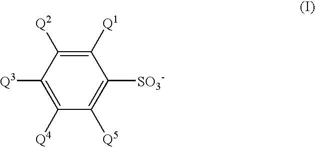

wherein, Q¹ to Q⁵ represent hydrogen, a hydroxyl group, a perfluoroalkyl group, an alkyl group, an alkoxy group or halogen; and a resin having a polymerization unit carrying a group unstable to an acid and polymerization unit of an alicyclic lactone of the following formula (IIa) or (IIb):

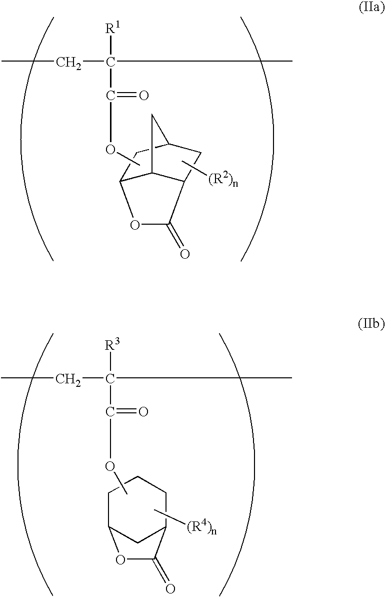

wherein, R¹, R², R³ and R⁴ represent each independently hydrogen or a methyl group, and n represents an integer of 1 to 3, and, when two or more groups of R² or R⁴ are present, they may be the same or different from each other.

### BACKGROUND OF THE INVENTION

1. Field of the Invention

The present invention relates to a chemical amplification type positive resist composition used in fine processing of semiconductors.

2. Prior Art

In fine processing of semiconductors, a lithography process using a resist composition is usually adopted. In lithography, it is theoretically possible to raise resolution higher when exposure wavelength is shorter, as represented by the formula of Rayleigh diffraction limit. The wavelength of a lithography exposure light source used in production of semiconductors is becoming shorter year by year, namely, g line having a wavelength of 436 nm, i line having a wavelength of 365 nm, KrF excimer laser having a wavelength of 248 nm and ArF excimer laser having a wavelength of 193 nm. As the exposure light source of the next generation, F₂ excimer laser having a wavelength of 157 nm is promising, and thereafter, soft X ray having a wavelength of 13 nm or less (EUV) is suggested as a light source.

Since light sources having shorter wavelength than that of g line and i line, such as excimer laser and the like have low illumination, it is necessary to enhance the sensitivity of a resist. Consequently, there are used so-called chemical amplification type resists utilizing the catalytic action of an acid generated by exposure and containing a resin having a group being dissociated by this acid.

However, in conventionally known chemical amplification type resist compositions, line edge roughness, namely, smoothness on pattern side wall lowers due to generation of standing waves and the like. Consequently, uniformity of line width deteriorates, and improvement in this point is desired.

### SUMMARY OF THE INVENTION

The object of the present invention is to provide a chemical amplification type positive resist composition suitable for excimer laser lithography such as ArF, KrF and the like, which shows excellent resolution and sensitivity and gives particularly improved line edge roughness.

The present inventors have found that excellent balance of various resist performances such as resolution, sensitivity and the like is obtained and line edge roughness can be improved by using an acid generator having a certain specific structure, as an acid generator constituting a chemical amplification type positive resist composition and by using a resin containing a polymerization unit obtained from a monomer having a certain specific structure, as a part of a polymerization unit in a resin. Thus, the present invention was completed.

Namely, the present invention relates to a chemical amplification type positive resist composition comprising an acid generator containing a benzenesulfonate ion of the formula (I):

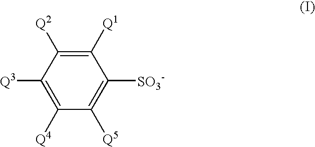

wherein, Q¹ to Q⁵ represent each independently hydrogen, a hydroxyl group, a perfluoroalkyl group having 1 to 12 carbon atoms, an alkyl group having 1 to 12 carbon atom, an alkoxy group having 1 to 12 carbon atoms or halogen; and a resin having a polymerization unit carrying a group unstable to an acid, being insoluble or poorly-soluble by itself in an alkali, but becoming alkali-soluble by the action of an acid, and having a polymerization unit of an alicyclic lactone of the following formula (IIa) or (IIb):

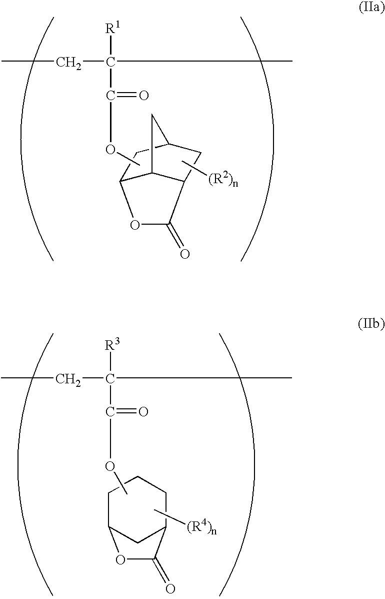

wherein, R¹, R², R³and R⁴ represent each independently hydrogen or methyl, and n represents an integer of 1 to 3, and, when two or more groups represented by R² or R⁴ are present, they may be the same or different from each other.

### DETAILED DESCRIPTION OF THE PREFERRED EMBODIMENTS

The acid generator used in a chemical amplification type resist composition has a mechanism that when radiation such as light and electron beam and the like is allowed to act on the substance itself or a resist composition containing the substance, the substance is decomposed to generate an acid.

The composition of the present invention is characterized in that an acid generator containing a benzenesulfonate ion of the above-mentioned formula (I) is used.

In the benzenesulfonate ion, Q¹ to Q⁵ represent hydrogen, a hydroxyl group, a perfluoroalkyl group having 1 to 12 carbon atoms, an alkyl group having 1 to 12 carbon atom, an alkoxy group having 1 to 12 carbon atoms or halogen. Examples of the perfluoroalkyl group having 1 to 12 carbon atoms include atrifluoromethyl group, perfluorobutyl group, perfluorooctyl group and the like, examples of the alkyl group having 1 to 12 carbon atoms include a methyl group, ethyl group, propyl group, isopropyl group, butyl group, pentyl group, hexyl group, cyclohexyl group, octyl group and the like, examples of the alkoxy group having 1 to 12 carbon atoms include a methoxy group, ethoxy group, propoxy group, butoxy group and the like, and examples of the halogen include fluorine and the like.

As the acid generator containing a benzenesulfonate ion, an acid generator containing at least one onium salt selected from triphenylsulfonium salts of the following formula (IIIa) and diphenyliodonium salts of the following formula (IIIb):

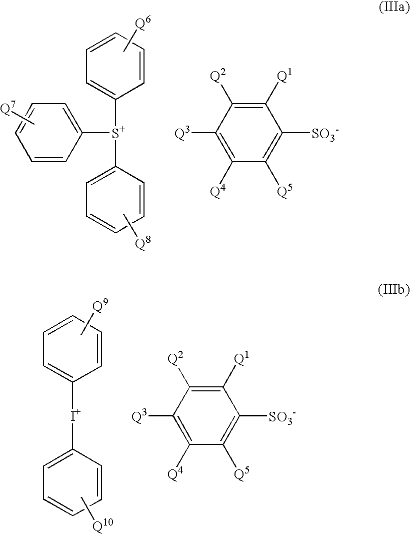

wherein Q⁶, Q⁷, Q⁸, Q⁹ and Q¹⁰ represent each independently hydrogen, a hydroxyl group, an alkyl group having 1 to 6 carbon atom or an alkoxy group having 1 to 6 carbon atoms is preferable. The alkyl group and alkoxy group represented by Q⁶, Q⁷, Q⁸, Q⁹ or Q¹⁰ may be linear or branched when the carbon number is 3 or more.

Specific examples of the alkyl group include a methyl group, ethyl group, propyl group, isopropyl group, butyl group, tert-butyl group, pentyl group, hexyl group and the like, and specific examples of the alkoxy group include a methoxy group, ethoxy group, propoxy group, butoxy group and the like.

As the triphenylsulfonium salt of the formula (IIIa) and the diphenyliodonium salt of the formula (IIIb), if there are commercially available products, they can be used as they are. Alternatively, they can be also produced according to a conventional method.

The triphenylsulfonium salt (IIIa) can be produced, for example, by a method in which the corresponding triphenylsulfonium bromide is reacted with a silver salt of the same sulfonic acid as the anion of the intended compound, a method in which the corresponding diphenyl sulfoxide, benzene-based compound and perfluoroalkanesulfonic acid are reacted in the presence of a trifluoroacetic anhydride according to the descriptions of Chem. Pharm. Bull., Vol. 29, 3753 (1981), a method in which the corresponding aryl Grignard's reagent is reacted with thionyl chloride, then, reacted with a triorganosilyl halide to give a triarylsulfonium halide, followed by reacted with a silver salt of the same sulfonic acid as the anion of the intended compound, according to the descriptions of JP-A-8-311018, and other methods.

A compound in which Q⁶, Q⁷ and/or Q⁸ in the formula (IIIa) is a hydroxyl group can be produced by treating a triphenylsulfonium salt having a tert-butoxy group on the benzene ring with the same sulfonic acid as the anion of the compound to eliminate a tert-butyl group, according to the descriptions of JP-A-8-311018.

The diphenyliodonium salt (IIIb) can be produced, for example, by a method in which iodyl sulfate and the corresponding aryl compound are reacted, then, the same sulfonic acid as the anion of the intended compound is added, according to the descriptions of J. Am. Chem. Soc., vol. 81, 342 (1959), a method in which into a mixture of acetic anhydride and fuming nitric acid is added iodine and trifluoroacetic acid to give a reaction product which is reacted with the corresponding aryl compound, then, the same sulfonic acid as the anion of the intended compound is added, a method in which concentrated sulfuric acid is dropped into a mixture of the corresponding aryl compound, acetic anhydride and potassium iodate and they are reacted, then, the same sulfonic acid as the anion of the intended compound is added, according to the descriptions of JP-A-9-179302, and other methods.

As the specific examples of triphenylsulfonium salts of the formula (IIIa) and diphenyliodonium salts of the formula (IIIb), the following compounds are listed.

tripheylsulfonium benzensulfonate,

tripheylsulfonium p-toluenesulfonate,

tripheylsulfonium triisopropylbenzenesulfonate,

tripheylsulfonium 2-fluorobenzensulfonate,

tripheylsulfonium 4-fluorobenzensulfonate,

tripheylsulfonium 2,4-difluorobenzensulfonate,

tripheylsulfonium 4-(n-butyl)benzensulfonate,

tripheylsulfonium 4-(n-octyl)benzensulfonate,

tripheylsulfonium 4-(n-dodecyl)benzensulfonate,

4-methylphenyldiphenylsulfonium benzenesulfonate,

4-methylphenyldiphenylsulfonium p-toluenesulfonate,

4-methylphenyldiphenylsulfonium triisopropylbenzenesulfonate,

4-methylphenyldiphenylsulfonium 2-fluorobenzenesulfonate,

4-methylphenyldiphenylsulfonium 4-fluorobenzenesulfonate,

4-methylphenyldiphenylsulfonium 2,4-difluorobenzenesulfonate,

4-methylphenyldiphenylsulfonium 4-(n-butyl)benzenesulfonate,

4-methylphenyldiphenylsulfonium 4-(n-octyl)benzenesulfonate,

4-methylphenyldiphenylsulfonium 4-(n-dodecyl)benzenesulfonate,

tris(4-methylphenyl)sulfonium benzenesulfonate,

tris(4-methylphenyl)sulfonium p-toluenesulfonate,

tris(4-methylphenyl)sulfonium triisopropylbenzenesulfonate,

tris(4-methylphenyl)sulfonium 2-fluorobenzenesulfonate,

tris(4-methylphenyl)sulfonium 4-fluorobenzenesulfonate,

tris(4-methylphenyl)sulfonium 2,4-difluorobenzenesulfonate,

tris(4-methylphenyl)sulfonium 4-(n-butyl)benzenesulfonate,

tris(4-methylphenyl)sulfonium 4-(n-octyl)benzenesulfonate,

tris(4-methylphenyl)sulfonium 4-(n-dodecyl)benzenesulfonate,

4-hydroxyphenyldiphenylsulfonium benzenesulfonate,

4-methoxyphenyldiphenylsulfonium p-toluenesulfonate,

4-methoxyphenyldiphenylsulfonium triisopropylbenzenesulfonate,

4-methoxyphenyldiphenylsulfonium 2-fluorobenzenesulfonate,

4-methoxyphenyldiphenylsulfonium 4-fluorobenzenesulfonate,

4-methoxyphenyldiphenylsulfonium 2,4-difluorobenzenesulfonate,

4-methoxyphenyldiphenylsulfonium 4-(n-butyl)benzenesulfonate,

4-methoxyphenyldiphenylsulfonium 4-(n-octyl)benzenesulfonate,

4-methoxyphenyldiphenylsulfonium 4-(n-dodecyl)benzenesulfonate,

tris(4-methylphenyl)sulfonium benzenesulfonate,

tris(4-methylphenyl)sulfonium p-toluenesulfonate,

tris(4-methylphenyl)sulfonium triisopropylbenzenesulfonate,

tris(4-methylphenyl)sulfonium 2-fluorobenzenesulfonate,

tris(4-methylphenyl)sulfonium 4-fluorobenzenesulfonate,

tris(4-methylphenyl)sulfonium 2,4-difluorobenzenesulfonate,

tris(4-methylphenyl)sulfonium 4-(n-butyl)benzenesulfonate,

tris(4-methylphenyl)sulfonium 4-(n-octyl)benzenesulfonate,

tris(4-methylphenyl)sulfonium 4-(n-dodecyl)benzenesulfonate,

tris(4-methoxyphenyl)sulfonium benzenesulfonate,

tris(4-methoxyphenyl)sulfonium p-toluenesulfonate

tris(4-methoxyphenyl)sulfonium triisopropylbenzenesulfonate,

tris(4-methoxyphenyl)sulfonium 2-fluorobenzenesulfonate,

tris(4-methoxyphenyl)sulfonium 4-fluorobenzenesulfonate,

tris(4-methoxyphenyl)sulfonium 2,4-difluorobenzenesulfonate,

tris(4-methoxyphenyl)sulfonium 4-(n-butyl)benzenesulfonate,

tris(4-methoxyphenyl)sulfonium 4-(n-octyl)benzenesulfonate,

tris(4-methoxyphenyl)sulfonium 4-(n-dodecyl)benzenesulfonate,

diphenyliodonium p-toluenesulfonate,

di(4-methoxyphenyl)iodonium p-toluenesulfonate,

di(4-tert-butylphenyl)iodonium benzenesulfonate,

di(4-tert-butylphenyl)iodonium p-toluenesulfonate,

di(4-tert-butylphenyl)iodonium triisopropylbenzenesulfonate,

di(4-tert-butylphenyl) iodonium 2-fluorobenzenesulfonate,

di(4-tert-butylphenyl)iodonium 4-fluorobenzenesulfonate,

di(4-tert-butylphenyl)iodonium 2,4-difluorobenzenesulfonate,

di(4-tert-butylphenyl)iodonium 4-(n-butyl)benzenesulfonate,

di(4-tert-butylphenyl)iodonium 4-(n-octyl)benzenesulfonate,

di(4-tert-butylphenyl)iodonium 4-(n-dodecyl)benzenesulfonate,

and the like.

Next, resin components constituting the resist composition of the present invention will be described. This resin has a polymerization unit carrying a group unstable to an acid, is insoluble or poorly-soluble by itself in an alkali, but becomes alkali-soluble by the action of an acid.

As the group unstable to an acid, groups which are dissociated by the action of an acid are listed.

As the group unstable to an acid in the present invention, there are listed specifically various esters of carboxylic acids, for example, alkyl esters typified by methyl esters and tert-butyl esters; acetal type esters such as methoxymethyl ester, ethoxymethyl ester, 1-ethoxyethyl ester, 1-isobutoxyethyl ester, 1-isopropoxyethyl ester, 1-ethoxypropyl ester, 1-(2-methoxyethoxy)ethyl ester, 1-(2-acetoxyethoxy)ethyl ester, 1-[2-(1-adamantyloxy)ethoxy]ethyl ester and, 1-[2-(1-adamantanecarbonyloxy)ethoxy]ethyl ester, tetrahydro-2-furyl ester and tetrahydro-2-pyranyl ester and the like; alicyclic esters such as isobornyl ester, 2-alkyl-2-adamantyl ester, 1-(1-adamantyl)-1-alkylalkyl ester; and the like.

The monomers induced into polymerization units having such carboxylates may be (meth)acrylic substances such as methacrylates and acrylates, and may also be substances obtained by bonding carboxylates to alicyclic monomers such as norbornene carboxylates, tricyclodecenecarboxylates, tetracyclodecene carboxylates and the like.

Of such monomers, those having bulky groups carrying alicyclic moieties such as 2-alkyl-2-adamantyl,

1- (1-adamantyl)-1-alkylalkyl are preferably used as the group which is dissociated by the action of an acid, since then excellent resolution is attained. As the monomers containing such bulky groups, 2-akyl-2-adamantyl (meth)acrylate,

1-(1-adamantyl)-1-alkylalkyl (meth)acrylate,

2-alkyl-2-adamantyl 5-norbornene-2-carboxylate,

1-(1-adamantyl)-1-alkylalkyl 5-norbornene-2-carboxylate and the like are listed. Particularly, 2-alkyl-2-adamantyl (meth)acrylate is preferably used because of excellent resolution. Typical examples of the 2-alkyl-2-adamantyl (meth)acrylate include 2-methyl-2-adamantyl acrylate,

2-methyl-2-adamantyl methacrylate, 2-ethyl-2-adamantyl acrylate, 2-ethyl-2-adamantyl methacrylate,

2-n-butyl-2-adamantyl acrylate and the like. Of them, particularly, 2-ethyl-2-adamantyl (meth)acrylates are preferably used because of excellent balance of sensitivity and heat resistance. If necessary, other monomers having a group which is dissociated by the action of an acid may also be used together.

The 2-alkyl-2-adamantyl (meth)acrylate can be produced usually by a reaction of 2-alkyl-2-adamantanol or metal salt thereof and an acrylic halide or methacrylic halide.

The resin in the present invention is characterized in that it contains a polymerization unit of an alicyclic lactone of the following formula (IIa) or (IIb):

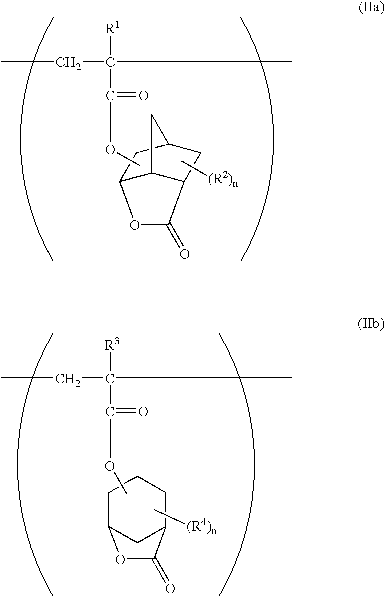

wherein, R¹, R², R³ and R⁴represent each independently hydrogen or methyl, and n represents an integer of 1 to 3, and, when two or more groups represented by R² or R⁴ are present, they may be the same or different from each other.

As the monomers induced into polymerization units of an alicyclic lactone of the formula (IIa) or (IIb), there are specifically listed (meth)acrylates of alicyclic lactones having a hydroxyl group as described below and mixtures thereof are listed, for example. These esters can be produced, for example, by a reaction of the corresponding alicyclic lactone having a hydroxyl group and (meth)acrylates (for example, see JP-A-2000-26446).

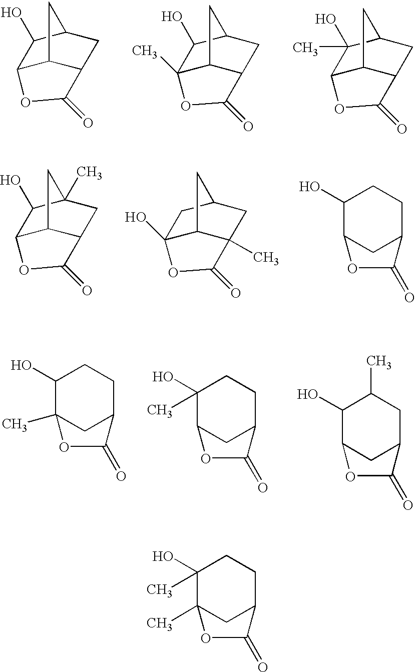

Any of a polymerization unit of 3-hydroxy-1-adamantyl (meth)acrylate, a polymerization unit of 3,5-dihydroxy-1-adamantyl (meth)acrylate and a polymerization unit of (meth)acryloyloxy-γ-butyrolactone in which the lactone ring may be optionally substituted with an alkyl has high polarity. Therefore, by the presence of any of them in a resin, in addition to the above-mentioned alicyclic lactone polymerization unit, adhesion to a substrate of a resist containing this is improved. The polymerization units contribute also to improvement in resolution of a resist.

The 3-hydroxy-1-adamantyl (meth)acrylate and 3,5-dihydroxy-1-adamantyl (meth)acrylate are commercially available, however, they can also be produced, for example, by reacting the corresponding hydroxyadamantane with (meth)acrylic acid or halide thereof. Further, the (meth)acryloyloxy-γ-butyrolactone can be produced by reacting acrylic acid or methacrylic acid with α- or β-bromo-γ-butyrolactone in which the lactone ring may optionally be substituted with an alkyl, or by reacting acrylic halide or methacrylic halide with α- or β-hydroxy-γ-butyrolactone in which the lactone ring may optionally be substituted with an alkyl.

Examples of the monomer induced into a polymerization unit of (meth)acryloyloxy-γ-butyrolactone include α-acryloyloxy-γ-butyrolactone, α-methacryloyloxy-γ-butyrolactone, α-acryloyloxy-β,β-dimethyl-γ-butyrolactone, α-methacryloyloxy-β,β-dimethyl-γ-butyrolactone, α-acryloyloxy-α-methyl-γ-butyrolactone, α-methacryloyloxy-α-methyl-γ-butyrolactone, β-acryloyloxy-γ-butyrolactone, β-methacryloyloxy-γ-butyrolactone, β-methacryloyloxy-α-methyl-γ-butyrolactone and the like.

A resin containing a polymerization unit of 2-norbornene has a stubborn structure in which the main chain directly has an alicyclic group, and manifests a property of excellent dry etching resistance. A polymerization unit of 2-norbornene can be introduced into the main chain, for example, by radical polymerization using an aliphatic unsaturated dicarboxylic anhydride such as maleic anhydride and itaconic anhydride together in addition to the corresponding 2-norbornene. Therefore, the polymerization unit of 2-norborne is formed by opening of the double bond and can be represented by the formula (IV). The polymerization unit of maleic anhydrie and the polymerization unit of itaconic anhydrie which is a polymerization unit of an alicyclic unsaturated dicarboxylic anhydride are formed by opening of the double bonds and can be represented by the formulae (V) and (VI).

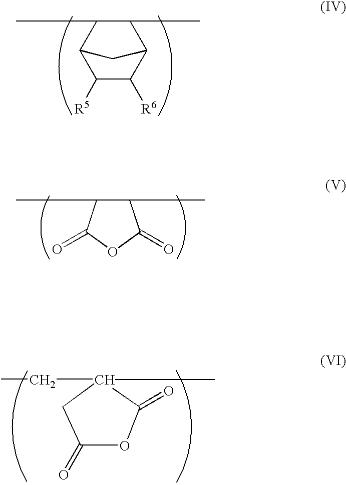

R⁵and R⁶in the formula (IV) represent each independently hydrogen, a hydroxyl group, an alkyl group having 1 to 4 carbon atom, a hydroxyalkyl group having 1 to 4 carbon atom optionally substituted with a halogen atom, a carboxyl group, a cyano group or a group of —COOZ (Z represents an alcohol residue), or R⁵ and R⁶can be joined to form a carboxylic anhydride residue —C(═O)OC(═O)—.

Specific examples of the alkyl group represented by R⁵ or R⁶ include methyl, ethyl, propyl, butyl, tert-butyl and the like, and specific examples of a hydroxyalkyl group optionally substituted with a halogen atom include hydroxymethyl, 2-hydroxyethyl,

2,2-ditrifluoro-2-hydroxyethyl and the like.

The group of —COOZ represented by R⁵ or R⁶ is a carboxyl ester. Examples of the alcohol residue represented by Z include alkyl groups having 1 to about 8 carbon atoms optionally substituted and 2-oxooxolan-3- or -4-yl and the like are mentioned, and substituents on the alkyl groups include, for example, a hydroxyl group, alicyclic hydrocarbon residues and the like.

Specific examples of the carboxylate residues of -COOZ represented by R⁵or R⁶include methoxycarbonyl, ethoxycarbonyl,

2-hydroxyethoxycarbonyl, tert-butoxycarbonyl,

2-oxooxolan-3-yloxycarbonyl, 2-oxooxalan-4-yloxycarbonyl,

1,1,2-trimethylpropoxycarbonyl,

1-cyclohexyl-1-methylethoxycarbonyl,

1-(4-methylcyclohexyl)-1-methylethoxycarbonyl,

1-(1-adamantyl)-1-methylethoxycarbonyl and the like.

As the monomer induced into a polymerization unit of 2-norbornene of the formula (IV), the following compounds are specifically listed, for example.

2-norbornene,

2-hydroxy-5-norbornene,

5-norbornene-2-carboxylic acid,

methyl 5-norbornene-2-carboxylate,

t-butyl 5-norbornene-2-carboxylate,

1-cyclohexyl-1-methylethyl 5-norbornene-2-carboxylate,

1-(4-methylcyclohexyl)-1-methylethyl 5-norbornene-2-carboxylate,

1-(4-hydroxycyclohexyl)-1-methylethyl 5-norbornene-2-carboxylate,

1-methyl-1-(4-oxocyclohexyl)ethyl 5-norbornene-2-carboxylate,

1-(1-adamantyl)-1-methylethyl 5-norbornene-2-carboxylate,

1-methylcyclohexyl 5-norbornene-2-carboxylate,

2-methyl-2-adamantyl 5-norbornene-2-carboxylate,

2-ethyl-2-adamantyl 5-norbornene-2-carboxylate,

2-hydroxy-1-ethyl 5-norbornene-2-carboxylate,

5-norbornene-2-methanol,

5-norbornene-2,3-dicarboxylic anhydride,

5-norbornene-2-(2,2-ditrifluoromethyl-2-hydroxy)eth yl and the like.

It is generally preferable that the resin used in the present invention contains a polymerization unit having a group unstable to an acid in an amount of 10 to 80 mol % though the preferable range varies depending on the kind of radiation for patterning exposure and the kind of a group unstable to an acid, and the like. When polymerization units of 2-alkyl-2-adamantyl (meth)acrylate and 1-(1-adamantyl)-1-alkylalkyl (meth)acrylate are used particularly as the group unstable to an acid, it is advantageous that the content of this unit is 15 mol % or more in the whole resin.

Regarding the other polymerization units which are not easily dissociated by the action of an acid, used in addition to the polymerization unit having a group unstable to an acid, it is preferable a polymerization unit of an alicyclic lactone of the formula (IIa) or (IIb) is contained in an amount of 90 to 10 mol % in the whole resin.

When a polymerization unit of 3-hydroxy-1-adamantyl (meth)acrylate, a polymerization unit of 3,5-dihydroxy-1-adamantyl (meth)acrylate, a polymerization unit of α-(meth)acryloyloxy-γ-butyrolactone, a polymerization unit of β-(meth)acryloyloxy-γ-butyrolactone, a polymerization unit of hydroxystyrene, a polymerization unit of 2-norbornene of the formula (IV), a polymerization unit of maleic anhydride of the formula (V) whih is a polymerization unit of an aliphatic unsaturated dicarboxylic anhydride, a polymerization unit of itaconic anhydride of the formula (VI) and the like are present as the other polymerization unit, it is preferable that the total amount thereof is from 10 to 75 mol % in the whole resin.

When 2-norbornenes and aliphatic unsaturated dicarboxylic anhydride are used as copolymerization monomers, since these show a tendency of poor polymerization, these are preferably used in excess amount in view of this point.

In the positive resist composition of the present invention, performance deterioration due to deactivation of an acid cause by leaving after exposure can be improved by adding basic compounds, particularly, basic nitrogen-containing organic compounds, for example, amines. Specific examples of the basic compound include those of the following formulae:

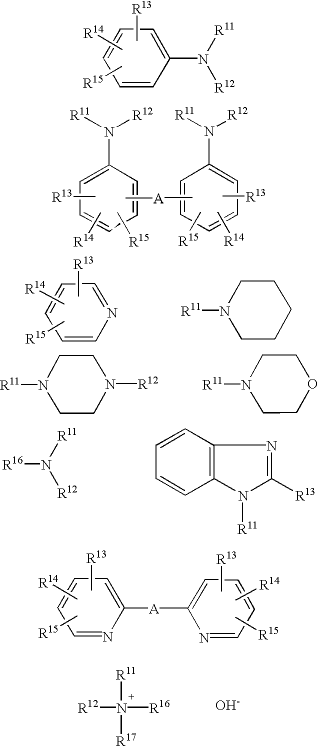

In the above formulae, R¹¹, R¹² and R¹⁷ represent each independently hydrogen, alkyl, cycloalkyl, aryl or alkoxy. These alkyl, cycloalkyl, aryl or alkoxy may be each independently substituted by a hydroxyl group, amino group or alkoxy group having 1 to 6 carbon atoms. This amino group may also be substituted with an alkyl group having 1 to 4 carbon atoms. This alkyl group preferably has about 1 to 6 carbon atoms, the cycloalkyl group preferably has about 5 to 10 carbon atoms, the aryl group preferably has about 6 to 10 carbon atoms, and the alkoxy group preferably has about 1 to 6 carbon atoms.

R¹³, R¹⁴ and R¹⁵ represent each independently hydrogen, alkyl, cycloalkyl, aryl or alkoxy. These alkyl, cycloalkyl, aryl or alkoxy may be each independently substituted by a hydroxyl group, amino group or alkoxy group having 1 to 6 carbon atoms. This amino group may also be substituted with an alkyl group having 1 to 4 carbon atoms. This alkyl group preferably has about 1 to 6 carbon atoms, the cycloalkyl group preferably has about 5 to 10 carbon atoms, the aryl group preferably has about 6 to 10 carbon atoms, and the alkoxy group preferably has about 1 to 6 carbon atoms.

R¹⁶ represents alkyl or cycloalkyl. The alkyl or cycloalkyl may be each independently substituted by a hydroxyl group, amino group or alkoxy group having 1 to 6 carbon atoms. This amino group may also be substituted with an alkyl group having 1 to 4 carbon atoms. This alkyl group preferably has about 1 to 6 carbon atoms, the cycloalkyl group preferably has about 5 to 10 carbon atoms.

A in the above formulae represents alkylene, carbonyl, imino, sulfide or disulfide. The alkylene preferably has about 2 to 6 carbon atoms.

When R¹¹ to R¹⁷ can have both of a linear structure and a branched structure, any of them may be permissible.

It is preferable that the resist composition of the present invention contains about 80 to 99.9 wt % of a resin and about 0.1 to 20 wt % of an acid generator based on the total weight of solid components.

When a basic compound is used as a quencher, the basic compound is preferably contained in an amount of about 0.01 to 1 wt % based on the total weight of solid components in the resist composition. This composition can also contain various additives such as sensitizers, solution inhibitors, other resins, surfactants, stabilizers, dyes and the like in small amount, if necessary.

The resist composition of the present invention is usually prepared into a resist solution in which the above-mentioned components are dissolved in a solvent, and coated on a substrate such as a silicon wafer and the like according to an ordinary method such as spin coating and the like. The solvent here used may be that dissolving various components, showing suitable drying speed, and giving a uniform and smooth coated film after evaporation of a solvent, and solvent usually used in this field can be used. Examples thereof include glycol ether esters such as ethylcellosolve acetate, methylcellosolve acetate and propylene glycol monomethyl ether acetate; esters such as ethyl lactate, butyl acetate, amyl acetate and ethyl pyruvate; ketones such as acetone, methyl isobutyl ketone, 2-heptanone and cyclohexanone; cyclic esters such as T-butyrolactone; and the like. These solvents may be used alone or in combination of two or more.

The resist film applied and dried on a substrate is subjected to exposure treatment for patterning, then, subjected to heating treatment for promoting a de-protecting group reaction, then, developed with an alkali developer. The alkali developer used here may be selected from various alkaline aqueous solutions used in this field, and generally, aqueous solutions of tetramethylammonium hydroxide and (2-hydroxyethyl)trimethylammonium hydroxide (generally called Choline) are often used.

### EXAMPLES

The following examples will illustrate the present invention further specifically, but do not limit the scope of the present invention. In examples, % and part representing content or use amount are by weight unless otherwise stated. The weigh-average molecular weight is a value determined by gel permeation chromatography using polystyrene as a standard article.

Acid Generator Synthesis Example 1:

[Synthesis of Acid Generatore (B1)]

(1) 34.0 parts of diphenyl sulfoxide and 340 parts of toluene were charged into a four-necked flask and cooled to 4° C. Then, 35.3 parts of trifluoroacetic anhydride and 25.3 parts of trifluoromethanesulfonic acid were charged and stirred at the same temperature for 30 minutes. After left to stand still, the lower layer was concentrated and 400 parts of ether was added to precipitate a crystal. The resulted crystal was filtrated, and washed with 100 parts of ether, to give 63.9 parts of 4-methylphenyldiphenylsulfonium trifluoromethanesulfonate.

(2) 63.9 parts of 4-methylphenyldiphenylsulfonium trifluoromethanesulfonate obtained in (1), 255.5 parts of methanol and 191.6 parts of ion exchanged water were added into a four-necked flask, and an aqueous solution prepared by dissolving 26.1 parts of potassium iodide into 130.5 parts of ion exchanged water was dropped into this while stirring at room temperature. After stirring for 3 hours at room temperature, the mixture was concentrated and extracted with 100 parts of chloroform. This chloroform solution was washed with water and concentrated, then, 300 parts of ethyl acetate was added to this to obtain 32.0 parts of 4-methylphenyldiphenylsulfonium iodide.

(3) 10.0 parts of dodecylbenzensulfonic acid and 40 parts of acetonitrile were charged into a four-necked flask, then, 3.7 parts of silver oxide was charged. After stirring for 3 hours at room temperature, the mixture was filtrated, and the filtrate was concentrated to obtain 8.8 parts of silver dodecylbenzenesulfonate.

(4) 4.3 parts of the sulfonium salt obtained in (2), and 64.1 parts of methanol were charged into a four-necked flask, then, a solution prepared by dissolving 4.6 parts of the silver salt obtained in (3) in 68.7 parts of methanol and 10.0 parts of ion exchanged water was dropped into this solution. The mixture was stirred at room temperature for 2 hours, then, filtrated. The filtrate was concentrated, then, extracted with 100 parts of chloroform, followed by washed with water and concentrated to obtain 6.4 parts of

4-methylphenyldiphenylsulfonium

4-(n-dodecyl)benzenesulfonate.

Resin Synthesis Example 1: [Synthesis of Resin A1]

2-Ethyl-2-adamantyl methacrylate, 5-methacryloyloxy-2,6-norbornenelactone and α-methacryloyloxy-γ-butyrolactone were mixed at a molar ratio of 2:1:1 (11.1 g:5.0 g:3.8 g), and to this was added 50 g of 1,4-dioxane to prepare a solution. To this was added 0.30 g of azobisisobutyronitrile as an initiator, and the mixture was heated up to 85° C. and stirred for 5 hours. Then, an operation of pouring into a large amount of n-heptane to cause precipitation of the resin was repeated three times for purification, to obtain a copolymer having a molecular weight of 9100 and a degree of dispersion of 1.72. This is called resin A1.

Resin Synthesis Example 2: [Synthesis of Resin A2]

2-Ethyl-2-adamantyl methacrylate, and 5-methacryloyloxy-2,6-norbornanecarbolactone were mixed at a molar ratio of 1:1 (12.42 g:11.11 g), and to this was added 47 g of 1,4-dioxane to prepare a solution. To this was added azobisisobutyronitrile as an initiator in a proportion of 3 mol % based on all monomers, then, the mixture was heated up to 80° C. and stirred for 6 hours. Then, an operation of pouring the reaction mass into a large amount of methanol to cause precipitation was repeated three times for purification of the resin, to obtain 15.8g (yield: 67.1%) of a copolymer having a molecular weight of 9637. This is called resin A2.

Resin Synthesis Example 3: [Synthesis of Resin A3]

29.8 g of 2-Ethyl-2-adamantyl methacrylate, 26.7 g of 5-methacryloyloxy-2,6-norbornenelactone, 7.5 g of norbornene and 7.8 g of maleic anhydride were charged (molar ratio, 30:30:20:20), and methyl isobutyl ketone was added in an amount of two-fold by weight of the total monomer weight, then, the mixture was heated up to 75° C. under a nitrogen atmosphere. To this was added azobisisobutyronitrile as an initiator in a proportion of 3 mol % based on the total monomer weight, and the mixture was heated at 80° C. for 15 hours. Then, an operation of pouring the reaction solution into a large amount of methanol to cause precipitation was repeated three times, to obtain 45.0 g (yield: 62.7%) of a copolymer having a molecular weight of 9010 and a degree of dispersion of 1.957. This is called resin A3.

Resin Synthesis Example 4: [Synthesis of Resin A4]

9.9 g of 2-Ethyl-2-adamantyl methacrylate, 8.9 g of 5-methacryloyloxy-2,6-norbornenelactone, 16.5 g of 5-norbornene-2- (2,2-ditrifluoromethyl-2-hydroxy)ethyle and 5.9 g of maleic anhydride were charged (molar ratio, 20:20:30:30), and methyl isobutyl ketone was added in an amount of two-fold by weight of the total monomer weight. Then, the mixture was heated up to 75° C. under a nitrogen atmosphere. To this was added dimethyl 2,2′-azobis(2-methylpropionate) as an initiator in a proportion of 3 mol % based on the total monomer weight, and the mixture was heated at 80° C. for 15 hours. Then, an operation of pouring the reaction solution into a large amount of methanol to cause precipitation was repeated three times, to obtain 5.0 g (yield: 23.8%) of a copolymer having a molecular weight of 2943 and a degree of dispersion of 1.142. This is called resin A4.

Resin Synthesis Example 5: [Synthesis of Resin AX]

2-Ethyl-2-adamantyl methacrylate and α-methacryloyloxy-γ-butyrolactone were charged at a molar ratio of 5:5 (40.0 parts:29.3 parts), and methyl isobutyl ketone was added in an amount of two-fold by weight of the total monomer weight to give a solution. To this was added azobisisobutyronitrile as an initiator in a proportion of 2 mol % based on the total monomer weight, and the mixture was heated at 80° C. for about 8 hours. Then, an operation of pouring the reaction solution into a large amount of heptane to cause precipitation was repeated three times, for purification. As a result, a copolymer having a weigh-average molecular weight of about 5600 was obtained. This copolymer is called resin AX.

Resin Synthesis Example 6: [Synthesis of Resin AY]

2-ethyl-2-adamantyl methacrylate, 3-hydroxy-1-adamantyl methacrylate and α-methacryloyloxy-γ-butyrolactone were charged at a molar ratio of 5:2.5:2.5 (20.0 parts:9.5 parts:7.3 parts), and methyl isobutyl ketone was added in an amount of two-fold by weight of the total monomer weight to give a solution. To this was added azobisisobutyronitrile as an initiator in a proportion of 2 mol % based on the total monomer weight, and the mixture was heated at 80° C. for about 8 hours. Then, an operation of pouring the reaction solution into a large amount of heptane to cause precipitation was repeated three times for purification. As a result, a copolymer having a weigh-average molecular weight of about 9200 was obtained. This copolymer is called resin AY.

Resin Synthesis Example 7: [Synthesis of Resin AZ]

2-Ethyl-2-adamantyl methacrylate, 3-hydroxy-1-adamantyl acrylate, norbornend and maleic anhydride were charged at a molar ratio of 2:2:3:3 (10.0 parts:9.0 parts:5.7 parts:5.9 parts), and methyl isobutyl ketone was added in an amount of two-fold by weight of the total monomer weight, and the mixture was heated up to 80° C. under a nitrogen atmosphere. To this was added azobisisobutyronitrile as an initiator in a proportion of 3 mol % based on the total monomer weight, and the mixture was heated at 80° C. for about 15 hours. Then, an operation of pouring the reaction solution into a large amount of methanol to cause precipitation was repeated three times, to obtain a copolymer (17.1 parts) having a weigh-average molecular weight of about 12160 and a degree of dispersion of 1.90. This copolymer is called resin AZ.

Next, examples of preparing resist compositions using the following acid generators B1 to B6 and Cl and evaluating the composition are shown below.

Acid generatore B1: 4-methylphenyldiphenylsulfonium 4-(n-dodecyl)benzenesulfonate

Acid generatore B2: triphenylsulfonium triisopropylbenzenesulfonate (manufactured by Toyo Gosei Co. Ltd.)

Acid generatore B3: tri(4-tert-butylphenyl)sulfonium triisopropylbenzenesulfonate (manufactured by Toyo Gosei Co. Ltd.)

Acid generatore B4: triphenylsulfonium 4-fluorobenzenesulfonate (manufactured by Toyo Gosei Co. Ltd.)

Acid generatore B5: triphenylsulfonium 2,4-difluorobenzenesulfonate (manufactured by Toyo Gosei Co. Ltd.)

Acid generatore B6: triphenylsulfonium 2-fluorobenzenesulfonate (manufactured by Toyo Gosei Co. Ltd.) Acid generatore C1: 4-methylphenyldiphenylsulfonium perfluorooctanesulfonate

### Examples 1 to 6 and Comparative Examples 1 to 4

Resins and acid generators shown in Table 1 were mixed with components shown below. The resulting mixture was filtrated through a fluorine resin filter having a pore diameter of 0.2 μm, to prepare a resist solution.

Resins: 10 parts (kinds are as shown in Table 1)

Acid generators:

kinds and quantities are as shown in Table 1

| | | |
|---|---|---|
| Quencher: 2,6-diisopropylaniline | 0.0075 | parts |
| Solvent: | | |
| Examples and Comparative Examples 1 to 4 | | |
| Propylene glycol monomethyl ether acetate | 26 | parts |
| 2-heptanone | 26 | parts |
| γ-butyrolactone | 3 | parts |
| Comparative Examples 5 to 7 | | |
| Propylene glycol monomethyl ether acetate | 57 | parts |
| γ-butyrolactone | 3 | parts |

“ARC-25-8” manufactured by Brewer was applied, and baked at 215° C. for 60 seconds to form an organic reflection prevention film having a thickness of 780 Å on a silicon wafer. On the silicon wafer, was spin-coated the above-mentioned resist solutions so that the film thickness after drying was 0.385 μm. After application of the resist solutions, pre-baking was conducted on a direct hot plate at temperatures shown in Table 1 for 60 seconds. The wafers carrying thus formed resist films were exposed to line and space patterns using an ArF excimer stepper [NSR ArF manufactured by Nikon Corp., NA=0.55, σ=0.6], while changing the exposure step-wise. After exposure, the wafers were subjected to post exposure bake on a hot plate at temperatures shown in Table 1 for 60 seconds, and subjected to paddle-development in a 2.38% tetramethylammonium hydroxide aqueous solution for 60 seconds Patterns after development were observed by a scanning electron microscope, to evaluate effective sensitivity and resolution.

Effective sensitivity: It was represented by the minimum exposure at which line and space pattern of 0.18 μm was 1:1 Resolution: It was represented by the minimum size of line and space pattern separated at the exposure at the effective sensitivity

Smoothness of pattern wall surface: The wall surface of isolated line patterns was observed by a scanning electron microscope. The surface more smooth than Comparative example 1 was judged to ∘, and the surface showing no change in smoothness as compared with Comparative example 1 was judged to X.

TABLE 1

| Example No. | Resin | Acid generator | Pre-bake (° C.) | PEB (° C.) |
|---|---|---|---|---|
| Example 1 | A1 | B1 (0.22 parts) | 130 | 130 |
| Example 2 | A1 | B2 (0.2 parts) | 130 | 130 |
| Example 3 | A1 | B3 (0.26 parts) | 130 | 130 |
| Example 4 | A1 | B4 (0.16 parts) | 130 | 130 |
| Example 5 | A1 | B5 (0.17 parts) | 110 | 110 |
| Example 6 | A1 | B6 (0.16 parts) | 110 | 110 |
| Example 7 | A2 | B2 (0.2 parts) | 140 | 140 |
| Example 8 | A3 | B2 (0.2 parts) | 140 | 140 |
| Example 9 | A4 | B2 (0.2 parts) | 130 | 130 |
| Comparative | A1 | C1 (0.2 parts) | 130 | 130 |
| example 1 | | | | |
| Comparative | A2 | C1 (0.2 parts) | 110 | 110 |
| example 2 | | | | |
| Comparative | A3 | C1 (0.2 parts) | 130 | 130 |
| example 3 | | | | |
| Comparative | A4 | C1 (0.2 parts) | 130 | 130 |
| example 4 | | | | |
| Comparative | AX | B2 (0.2 parts) | 130 | 130 |
| example 5 | | | | |
| Comparative | AY | B2 (0.2 parts) | 150 | 145 |
| example 6 | | | | |
| Comparative | AZ | B2 (0.2 parts) | 130 | 130 |
| example 7 | | | | |

TABLE 2

| | Effective | | Smoothness of |
|---|---|---|---|
| | sensitivity | Resolution | pattern wall |
| Example No. | mJ/cm² | μm | surface |
| Example 1 | 40 | 0.15 | ◯ |
| Example 2 | 68 | 0.15 | ◯ |
| Example 3 | 106 | 0.16 | ◯ |
| Example 4 | 22 | 0.16 | ◯ |
| Example 5 | 33 | 0.16 | ◯ |
| Example 6 | 42 | 0.16 | ◯ |
| Example 7 | 52 | 0.16 | ◯ |
| Example 8 | 54 | 0.16 | ◯ |
| Example 9 | 33 | 0.16 | ◯ |
| Comparative | 17 | 0.15 | — |
| example 1 | | | |
| Comparative | 71 | 0.16 | X |
| example 2 | | | |
| Comparative | 26 | 0.16 | X |
| example 3 | | | |
| Comparative | 20 | 0.16 | X |
| example 4 | | | |
| Comparative | 28 | 0.17 | ◯ |
| example 5 | | | |
| Comparative | 62 | 0.17 | ◯ |
| example 6 | | | |
| Comparative | 57 | 0.17 | ◯ |
| example 7 | | | |

As shown in table 2, the resist compositions of the examples are excellent in line edge roughness as compared with the comparative examples and show good resolution and sensitivity.

The chemical amplification type positive resist composition of the present invention gives resist patterns showing remarkably improved line edge roughness, and also good in resolution and sensitivity. Therefore, this composition is suitable to lithography using ArF excimer laser and the like, and gives resist patterns of higher performances.

What is claimed is:

1. A chemical amplification type positive resist composition comprising
an acid generator containing a benzenesulfonate ion of the formula (I): 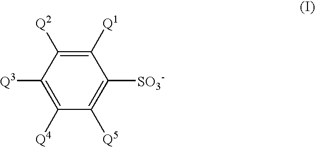
wherein, Q¹ to Q⁵ represent each independently hydrogen, a hydroxyl group, a perfluoroalkyl group having 1 to 12 carbon atoms, an alkyl group having 1 to 12 carbon atom, an alkoxy group having 1 to 12 carbon atoms or halogen; and a resin having a polymerization unit carrying a group unstable to an acid, being insoluble or poorly-soluble by itself in an alkali, but becoming alkali-soluble by the action of an acid, and having polymerization unit of an alicyclic lactone of the following formula (IIa) or (IIb): 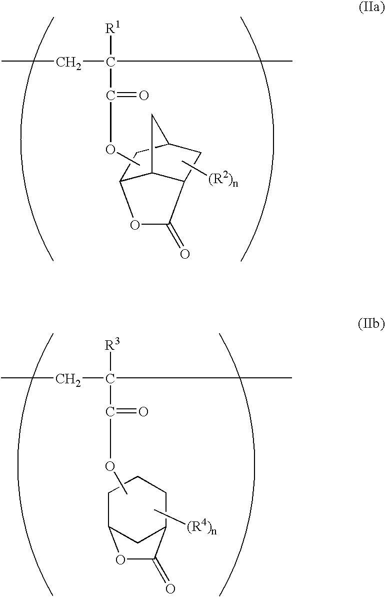
wherein, R¹, R², R³and R⁴represent each independently hydrogen or a methyl group, and n represents an integer of 1 to 3, and, when two or more groups of R² or R⁴ are present, they may be the same or different from each other.

2. The composition according to claim 1 wherein the acid generator containing a benzenesulfonate ion of the formula (I) is an acid generator containing at least one onium salt selected from triphenylsulfonium salts of the following formula (IIIa) and diphenyliodonium salts of the following formula (IIIb): 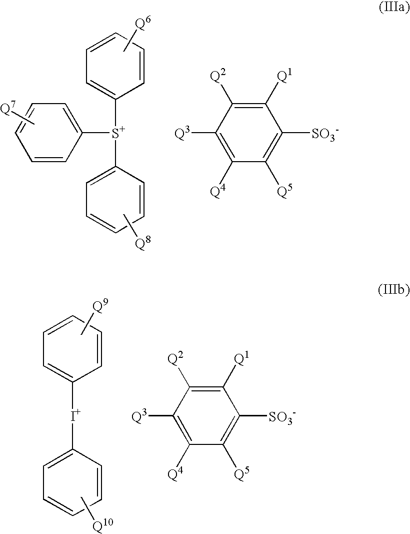
wherein, Q¹ to Q⁵ are as defined in claim 1, Q⁶ to Q¹⁰ represent each independently hydrogen, a hydroxyl group, an alkyl group having 1 to 6 carbon atom or an alkoxy group having 1 to 6 carbon atoms.

3. The composition according to claim 1 wherein the content of the polymerization unit carrying a group unstable to an acid, in the resin is from 10 to 80 mol %.

4. The composition according to any of claims 1 wherein the polymerization unit carrying a group unstable to an acid is a polymerization unit of 2-alkyl-2-adamantyl (meth)acrylate.

5. The composition according to claim 4 wherein the polymerization unit of 2-alkyl-2-adamantyl (meth)acrylate is 2-ethyl-2-adamantyl (meth)acrylate.

6. The composition according to any of claims 1 wherein the resin further contains at least one polymerization unit selected from a polymerization unit of 3-hydroxy-1-adamantyl (meth)acrylate, a polymerization unit of 3,5-dihydroxy-1-adamantyl (meth)acrylate, and a polymerization unit of (meth)acryloyloxy-γ-butyrolactone in which the lactone ring may be optionally substituted with an alkyl.

7. The composition according to any of claims 1 wherein the resin further contains a polymerization unit of 2-norbornene and a polymerization unit of an aliphatic unsaturated dicarboxylic anhydride.

8. The composition according to any of claims 1 wherein the composition further contains amines as a quencher.
